(19) United States
(12) Patent Application Publication
(10) Pub. No.: US 2015/0014819 A1
(43) Pub. Date: Jan. 15, 2015

(54) UNDERLYING FILM COMPOSITION FOR IMPRINTS AND PATTERN FORMING METHOD USING THE SAME

(71) Applicant: FUJIFILM Corporation, Tokyo (JP)

(72) Inventors: Akiko HATTORI, Haibara-gun (JP); Hirotaka KITAGAWA, Haibara-gun (JP); Yuichiro ENOMOTO, Haibara-gun (JP); Tadashi OOMATSU, Haibara-gun (JP)

(73) Assignee: FUJIFILM CORPORATION, Tokyo (JP)

(21) Appl. No.: 14/495,289

(22) Filed: Sep. 24, 2014

Related U.S. Application Data
(63) Continuation of application No. PCT/JP2013/051564, filed on Jan. 25, 2013.

(30) Foreign Application Priority Data
Mar. 29, 2012 (JP) 2012-076018

(51) Int. Cl. C08F 122/10; C08F 120/30; C08L 35/02; H01L 21/027; C08K 5/3445; C08K 5/21; B29C 35/08; H01L 29/06; C08F 120/28; C08L 33/14

(52) U.S. Cl. CPC C08F 122/105; C08F 120/28; C08F 120/30; C08L 35/02; C08L 33/14; C08K 5/3445; C08K 5/21; B29C 35/0805; H01L 29/06; H01L 21/0271; B29C 2035/0827; B29L 2011/00
USPC 257/618; 525/329.5; 524/559; 524/558; 428/522; 548/303.4; 564/60; 548/323.5; 264/496

(57) ABSTRACT

Provided is an underlying film composition for imprints showing a good adhesiveness with a base and capable of reducing failure or defect of resist pattern. The underlying film composition for imprints comprising a curable main component and a urea-based crosslinking agent.

### CROSS-REFERENCE TO RELATED APPLICATIONS

This application is a Continuation of PCT International Application No. PCT/JP2013/051564 filed on Jan. 25, 2013, which claims priority under 35 U.S.C §119(a) to Japanese Patent Application No. 2012-076018, filed on Mar. 29, 2012. The above application is hereby expressly incorporated by reference, in its entirety, into the present application.

### TECHNICAL FIELD

The present invention relates to a underlying film composition for imprints disposed between a base and a curable composition for imprints, further to a pattern forming method using the underlying film composition for imprints, further to a method of manufacturing a device with the aid of the pattern forming method, further to a laminate using the underlying film composition for imprints, and a device incorporating the laminate.

In more details, the present invention relates to an underlay film composition for imprints, which are used for forming micropatterns by photoirradiation, and are used for manufacturing semiconductor integrated circuit; flat screen; microelectro-mechanical system (MEMS); sensor device; optical disk; magnetic recording media such as high density memory disk; optical components such as grating and relief hologram; nanodevice; optical device; optical film and polarizing device for manufacturing flat panel display; thin film transistor, organic transistor, color filter, overcoat layer, pillar component, rib component for aligning liquid crystal for liquid crystal display; microlens array; immunoassay chip; DNA chip; microreactor; nanobio device, optical waveguide; optical filter; photonic liquid crystal; and mold for imprints.

### BACKGROUND ART

Nanoimprint technology is a development advanced from embossing technology well known in the art of optical disc production, which comprises pressing a mold original with an embossed pattern formed on its surface (this is generally referred to as “mold”, “stamper” or “template”) against a resin to thereby accurately transfer the micropattern onto the resin through mechanical deformation of the resin. In this, when a mold is once prepared, then microstructures such as nanostructures can be repeatedly molded, and therefore, this is economical, and in addition, harmful wastes and discharges from this nanotechnology are reduced. Accordingly these days, this is expected to be, applicable to various technical fields.

Two methods of nanoimprint technology have been proposed; one is a thermal nanoimprint method using a thermoplastic resin as the material to be worked, and the other is a photonanoimprint method using a photocurable composition. In the thermal nanoimprint method, a mold is pressed against a polymer resin heated up to a temperature higher than the glass transition temperature thereof, then the resin is cooled and thereafter released from the mold to thereby transfer the microstructure of the mold onto the resin on a substrate. The method is applicable to various resin materials and glass materials and is expected to be applicable to various fields.

On the other hand, in the photonanoimprint method where a photo-curable composition is cured by photoirradiation through a transparent mold or a transparent substrate, the transferring material does not require heating in pressing it against the mold, and therefore the method enables room-temperature imprinting. Recently, new developments having the advantages of the above two as combined, have been reported, including a nanocasting method and a reversal imprint method for forming three-dimensional structures.

For the nanoimprint methods as above, proposed are applied technologies mentioned below.

In the first technology, the molded pattern itself has a function, and is applied to various elements in nanotechnology and to structural members. Its examples include various micro/nano optical elements and high-density recording media, as well as structural members in optical films, flat panel displays, etc.

The second technology is for hybrid-molding of microstructures and nanostructures, or for construction of laminate structures through simple interlayer positioning, and this is applied to production of .mu.-TAS (micro-total analysis system) and biochips.

In the third technology, the formed pattern is used as a mask and is applied to a method of processing a substrate through etching or the like.

In these technologies, high-precision positioning is combined with high-density integration; and in place of conventional lithography technology, these technologies are being applied to production of high-density semiconductor integrated circuits and transistors in liquid-crystal displays, and—also to magnetic processing for next-generation hard discs referred to as patterned media. Recently, the action on industrialization of the above-mentioned nanoimprint technologies and their applied technologies has become active for practical use thereof.

As activities regarding the photonanoimprint method—have increased, an issue of adhesiveness between a substrate and a curable composition for imprints has been gaining more attention. In more details, the curable composition for imprints is generally applied to the surface of the substrate to form a layer, and is cured by photoirradiation while being kept under a mold, but the curable composition for imprints may adhere onto the mold when the mold is separated thereafter. Poor separability of the mold may degrade formability of the resultant patterns. This is ascribable to a part of the curable composition for imprints remaining on the mold.

There has therefore been a need to enhance adhesiveness between the base and the curable composition for imprints. Known methods of enhancing the adhesiveness between the base and the curable composition for imprints are described in Patent Literature 1 and Patent Literature 2. More specifically, according to Patent Literature 1, a polymerizable monomer having a group capable of interacting with the base is used to enhance the adhesiveness between the base and the curable composition for imprints. According to Patent Literature 2, an aromatic polymer is used to enhance the adhesiveness between the base and the curable composition for imprints.

### CITATION LIST

### Patent Literature

[Patent Literature 1] JP-T-2009-503139
[Patent Literature 2] JP-T-2011-508680

### SUMMARY OF THE INVENTION

### Technical Problem

In many cases of pattern transfer process based on imprinting, an underlying film (adhesive layer) has been used to improve the adhesiveness between the curable composition for imprints (resist) and the base. As a matter of course, such underlying film is required to have a large adhesiveness with the base and the curable composition for imprints, and, to have a large strength. While the underlying film composition in Patent Literature 1 is supposed to be enhanced in film strength by adding a melamine-based crosslinking agent, the present inventors found out from our investigation that addition of the melamine-based crosslinking agent reduces the adhesiveness with the base. It was also found that the addition of the melamine-based crosslinking agent induces separation failure due to reduced adhesiveness with the base. This was found to be ascribable to damage of the melamine-based crosslinking agent induced by short-wavelength component in ultraviolet radiation which is generally used for curing the curable composition for imprints.

It is therefore a subject of the present invention to solve the above-described problems in the prior art, and an object is to provide a underlying film composition capable of giving a resist which shows a good adhesiveness with the base, and is less likely to cause failure or defect. It is a further object to provide an underlying film composition less likely to be degraded under ultraviolet irradiation.

### Solution to Problem

In such circumstances, the present inventors found out from our investigations that the above-described problems are solved by using a urea-based crosslinking agent as the crosslinking agent. Specifically, the problems were solved by the configuration <1>, preferably by configurations <2> to <11> below.

<1> An underlying film composition for imprints comprising a curable main component and a urea-based crosslinking agent.
<2> The underlying film composition for imprints of <1>, wherein the urea-based crosslinking agent is a compound represented by the formula (I) below:

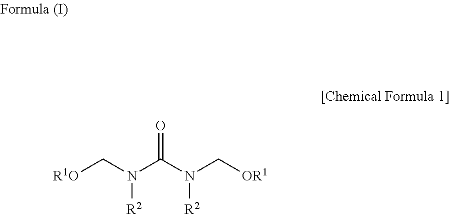

(in the formula (I), each R¹ independently represents a hydrogen atom, or C₁₋₈ straight-chain or branched alkyl group, and each R² represents a hydrogen atom, or a C₁₋₁₁ substituent which may combine to each other to form a ring.)
<3> The underlying film composition for imprints of <1>, wherein the urea-based crosslinking agent is represented by any one of the formulae (II) to (V) below:

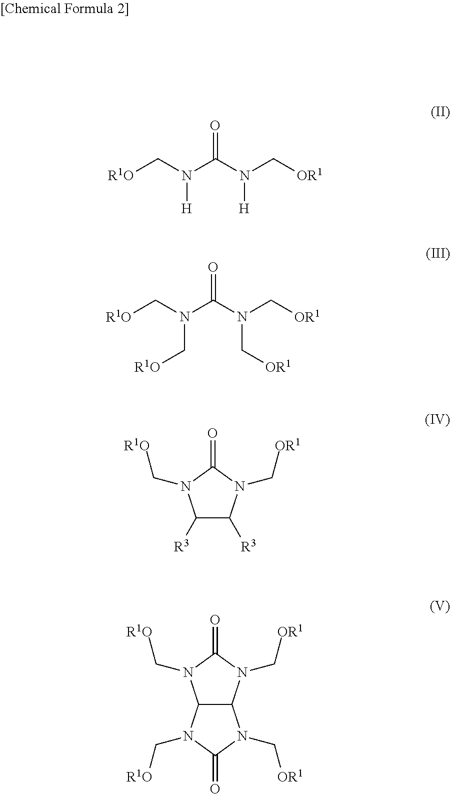

(in the formulae (II) to (V), each R¹ independently represents a hydrogen atom, or C₁₋₈ straight-chain or branched alkyl group. Each R³ independently represents a hydrogen atom, hydroxy group, or C₁₋₈ straight-chain or branched alkoxy group.)
<4> The underlying film composition for imprints of <3>, wherein, in the formulae (II) to (V), each R¹ independently represents a hydrogen atom or methyl group, and each R³ independently represents a hydrogen atom, hydroxy group or methoxy group.
<5> A cured product obtained by curing the underlying film composition for imprints described in any one of <1> to <4>.
<6> A laminate comprising a base, an underlying film obtained by curing the underlying film composition for imprints described in any one of <1> to <4>, and a cured product of a curable composition for imprints.
<7> A pattern forming method comprising:

applying the underlying film composition for imprints described in any one of <1> to <4> on a base, to form an underlying film;

applying a curable composition for imprints onto the underlying film;

curing the curable composition for imprints by photo-irradiation while keeping the curable composition for imprints and the underlying film held between the base and a mold with a fine pattern; and

releasing the mold.

<8> The pattern forming method of <7>, comprising:

applying the curable composition for imprints, after applying the underlying film composition for imprints onto the base, and after curing a part of the underlying film composition for imprints by heating or photo-irradiation.

<9> A method of manufacturing a semiconductor device, the method comprising the pattern forming method described in <7> or <8>.
<10> An adhesion improving agent for improving adhesion between a curable composition for imprints and a base, the agent comprising a urea-based crosslinking agent.
<11> The adhesion improving agent of <10>, wherein the urea-based crosslinking agent is a compound represented by the formula (I) below:

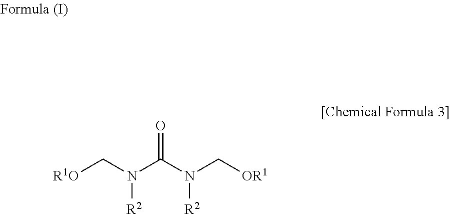

(in the formula (I), each R¹ independently represents a hydrogen atom, or C₁₋₈ straight-chain or branched alkyl group, and each R² independently represents a hydrogen atom, or a C₁₋₁₁ substituent which may combine to each other to form a ring.)
<12> A semiconductor device manufactured by the method of manufacturing a semiconductor device of <9>.

### Advantageous Effects of Invention

According to the present invention, it now became possible to enhance the adhesiveness between the resist and the base, to thereby reduce the separation failure during imprinting, and to improve service life of mold by virtue of suppressed adhesion of resist onto the mold. It also became possible to suppress increase in defects possibly caused by short-wavelength component in ultraviolet radiation irradiated to cure the resist, and to suppress the adhesive from degrading due to short-wavelength component in ultraviolet radiation to be irradiated to cure the resist, so that there is now provided a wider range of choice of illumination source of light used for curing the resist. Now a light source emitting shorter wavelength with higher energy becomes usable to reduce tact time.

### BRIEF DESCRIPTION OF DRAWINGS

FIG. 1 is a drawing illustrating an exemplary process of manufacturing in which the curable composition for imprints is used for etching of a base.

### DESCRIPTION OF EMBODIMENTS

The present invention will be explained in detail below. As used herein, the numerical ranges expressed with “to” are used to mean the ranges including the values indicated before and after “to” as lower and upper limits.

In this specification, “(meth)acrylate” means acrylate and methacrylate, “(meth)acryl” means acryl and methacryl, and “(meth)acryloyl” means acryloyl and methacryloyl. Also in this specification, “monomer” is synonymous to “monomer”. The monomer in the context of the present invention is discriminated from oligomer and polymer, and means a sort of compound having a weight-average molecular weight of 1,000 or smaller. In this specification, “functional group” means a sort of group which takes part in polymerization reaction.

“Imprint” in the context of the present invention means pattern transfer in a size of 1 nm to 10 mm, and more preferably means pattern transfer in a size of approximately 10 nm to 100 μm (nano-imprinting).

In this specification, notation of group (atomic group) without being preceded by “substituted” or “unsubstituted”, is used to encompass not only group having no substituent, but also group having substituent. For example, “alkyl group” encompass not only alkyl group having no substituent (unsubstituted alkyl group), but also alkyl group having substituent (substituted alkyl group).

The underlying film composition of the present invention characteristically contains a curable main component and a urea-based crosslinking agent. By using the urea-based crosslinking agent, the underlying film will be made durable against a wide range of light sources.

### <Urea-Based Crosslinking Agent>

The urea-based crosslinking agent in the present invention means a crosslinking agent containing a urea group. The urea-based crosslinking agent may also be a resin, preferably with a molecular weight of 50 to 10,000, and more preferably with 100 to 5,000.

The urea-based crosslinking agent is preferably a compound represented by the formula (I) below:

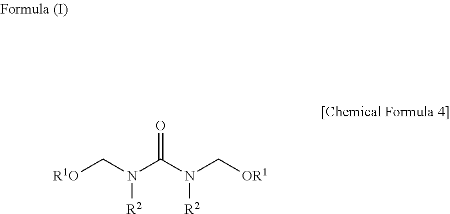

(in the formula (I), each R¹ independently represents a hydrogen atom, or C₁₋₈ straight-chain or branched alkyl group, and each R² represents a hydrogen atom, or a C₁₋₁₁ substituent which may combine to each other to form a ring.)

Each R¹ independently, and preferably, represents a hydrogen atom or C₁₋₃ straight-chain or branched alkyl group, and more preferably represents a hydrogen atom, methyl group or ethyl group, wherein hydrogen atom or methyl group is preferable.

The formula (I) is preferably represented by any of the formulae (II) to (V) below:

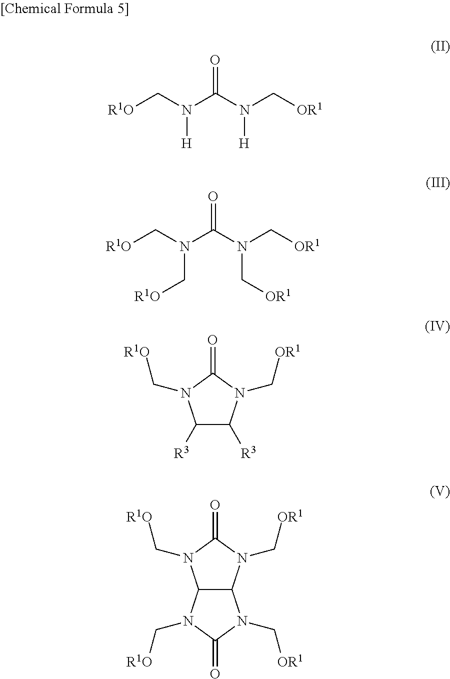

(in the formulae (II) to (V), each R¹ independently represents a hydrogen atom, or C₁₋₈ straight-chain or branched alkyl group. Each R³ independently represents a hydrogen atom, hydroxy group, or C₁₋₈ straight-chain or branched alkoxy group.)

In the formulae (II) to (V), R¹ is synonymous to R¹ in the formula (I) with the same preferable ranges. R³ preferably represents a hydrogen atom, hydroxy group, methoxy group or ethoxy group, and more preferably hydrogen atom, hydroxy group or methoxy group.

Specific examples of the urea-based crosslinking agent include methylated urea-based crosslinking agents such as tetrakis(methoxymethyl)glycoluril, 4,5-dimethoxy-1,3-bis(methoxymethyl)imidazolidin-2-one, tetrakis(butoxymethyl)glycoluril, tetrakis(ethoxymethyl)glycoluril, tetrakis(isopropoxymethyl)glycoluril, tetrakis(amyloxymethyl)glycoluril, and tetrakis(hexoxymethyl)glycoluril.

They are commercially available from Sanwa Chemical Co., Ltd. as Nikalac MX-270, Nikalac MX-280 and Nikalac MX-290; from American Cyanamid Co. as Powderlink 1174; from Cytec Industries Inc. as Cymel 1170, all of them are preferably used.

Also monomers of the above-described resins are usable, which are exemplified by the compounds listed below, including dimethoxymethylurea.

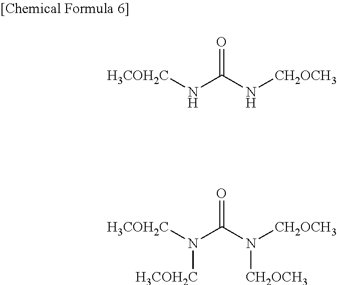

The content of the urea-based crosslinking agent is typically 1 to 50% by mass of the total components, but excluding the solvent, of the underlying film composition of the present invention, and preferably 5 to 30% by mass. Only a single species of the crosslinking agent thereof, or two or more species thereof in a mixed manner may be used. When two or more species are used, the total content preferably falls in the range described above.

### <Curable Main Component>

The underlying film composition of the present invention contains a curable main component. Both of heat-curable and photo-curable resins are usable as the curable main component, wherein the heat curable resin is preferable.

The curable main component preferably has a molecular weight of 400 or larger. Both of low-molecular-weight compound and polymer are usable, wherein the polymer is preferable. The curable main component preferably has a molecular weight of 500 or larger, more preferably 1000 or larger, and furthermore preferably 3000 or larger. The upper limit of the molecular weight is preferably 200000 or smaller, more preferably 100000 or smaller, and furthermore preferably 50000 or smaller. By limiting the molecular weight to 400 or larger, the components may be prevented from vaporizing in a more effective manner.

The content of the curable main component is preferably 30% by mass or more of the total components but excluding the solvent, more preferably 50% by mass or more, and furthermore preferably 70% by mass or more. Two or more species of the curable main component may be used. The total contents in this case preferably falls in the above-described ranges.

### <Solvent>

The underlying film composition of the present invention preferably contains a solvent. Preferably, the solvent has a boiling point at normal pressure of from 80 to 200° C. Regarding the type of the solvent, any solvent capable of dissolving the underlying film composition may be used. Preferred are solvents having at least any one of an ester structure, a ketone structure, a hydroxyl group and an ether structure. Concretely, the solvent is preferably one or more selected from propylene glycol monomethyl ether acetate, cyclohexanone, 2-heptanone, gamma-butyrolactone, propylene glycol monomethyl ether, ethyl lactate. Most preferred is a solvent containing propylene glycol monomethyl ether acetate as securing coating uniformity.

The content of the solvent in the underlying film composition of the present invention is optimally adjusted depending on the viscosity of the components excluding the solvent, coatability, and target thickness of the film. From the viewpoint of improving the coatability, the amount of addition may be 70% by mass or more of the total components, preferably 90% by mass or more, furthermore preferably 95% by mass or more, and still more preferably 99% by mass or more.

The underlying film composition of the present invention may contain, as other component, at least one species selected from surfactant, heat polymerization initiator, polymerization inhibitor and catalyst. The content of any of these components is preferably 50% by mass or less of the total components excluding the solvent.

### <Surfactant>

The underlying film composition of the present invention for imprints may contain a surfactant. The content of the surfactant is, for example, 0.00001 to 5% by mass of the total components excluding the solvent, preferably 0.0001 to 2% by mass, and furthermore preferably 0.005 to 1% by mass. When two or more species of surfactant are used, the total content falls in the above-described ranges. By adjusting the content of surfactant in the composition to 0.00001 to 5% by mass, a good effect of uniformity of coating may be obtained. As the surfactant, preferred are nonionic surfactants.

Preferably, the composition comprises at least one of a fluorine-containing surfactant, a silicone-type surfactant and a fluorine-containing silicone-type surfactant. More preferably, the composition comprises both a fluorine-containing surfactant and a silicone-type surfactant, or a fluorine-containing silicone-type surfactant. The most preferably, the composition comprises a fluorine-containing silicone-type surfactant. As the fluorine-containing surfactant and the silicone-type surfactant, preferred are nonionic surfactants.

“Fluorine-containing silicone-type surfactant” as referred to herein means a surfactant satisfying both the requirement of a fluorine-containing surfactant and that of a silicone-type surfactant.

Using the surfactant of the type may solve the problem of coating failures such as striation and flaky pattern formation (drying unevenness of resist film) that may occur when the composition for imprints of the invention is applied onto substrates on which various films are formed, for example, onto silicon wafers in semiconductor production, or onto glass square substrates, chromium films, molybdenum films, molybdenum alloy films, tantalum films, tantalum alloy films, silicon nitride films, amorphous silicon films, tin oxide-doped indium oxide (ITO) films or tin oxide films in production of liquid-crystal devices. In particular, when the above-mentioned surfactant is added to the underlying film composition for imprints of the invention, the coating uniformity of the composition can be greatly improved; and in coating with it using a spin coater or a slit scan coater, the composition ensures good coating aptitude irrespective of the size of the substrate to which it is applied.

Examples of the nonionic fluorine-containing surfactant usable in the invention include Fluorad FC-430, FC-431 (Sumitomo 3M's trade names); Surflon S-382 (Asahi Glass's trade name); Eftop EF-122A, 122B, 122C EF-121, ‘EF-126, EF-127, MF-100 (Tochem Products' trade names); PF-636, PF-6320, PF-656, PF-6520 (Omnova Solution's trade names); Futagent FT250, FT251, DFX18 (Neos' trade names); Unidyne DS-401, DS-403, DS-451 (Daikin's trade names); Megafac 171, 172, 173, 178K, 178A, F780F (DIC's trade names).

Further, examples of the silicone-based nonionic surfactant (manufactured by Dainippon Ink and Chemicals Co., Ltd.), trade name SI-10 series (manufactured by Takemoto Oil & Fat Co., Ltd.), Megaface pane Todd 31 KP (Shin-Etsu Chemical Co., Ltd.), and the like −341.

Examples of the fluorine-containing silicone-type surfactant include X-70-090, X-70-091, X-70-092, X-73-093 (Shin-Etsu Chemical's trade names); Megafac R-08, XRB-4 (DIC's trade names).

### <Heat Polymerization Initiator>

The underlying film composition of the present invention may contain a heat polymerization initiator, for the purpose of initiating crosslinking.

Particularly preferable examples of the thermal polymerization initiator preferably used herein include thermal radical initiator composed of organic peroxide or organic azo compound. Examples of the organic peroxide include ketone peroxides such as Perhexa H; peroxyketals such as Perhexa TMH; hydroperoxides such as Perbutyl H-69; dialkyl peroxides such as Percumyl D, Perbutyl C, and Perbutyl U; diacyl peroxides such as Nyper BW; peroxyesters such as Perbutyl Z and Perbutyl L; peroxydicarbonates such as Perloyl TCP; all commercially available from NOF Corporation, diisobutyryl peroxide, cumylperoxyneodecanoate, di-n-propylperoxydicarbonate, diisopropylperoxydicarbonate, di-see-butylperoxydicarbonate, 1,1,3,3-tetramethylbutylperoxyneodecanoate, di(4-tert-butylchlorohexyl)peroxydicarbonate, di(2-ethylhexyl)peroxydicarbonate, tert-hexylperoxyneodecanoate, tert-butylperoxyneodecanoate, tert-butylperoxyneoheptanoate, tert-hexylperoxypivalate, tert-butylperoxypivalate, di(3,5,5-trimethylhexanoyl)peroxide, dilauroyl peroxide, 1,1,3,3-tetramethylbutylperoxy-2-ethylhexanoate, disuccinic acid peroxide, 2,5-dimethyl-2,5-di(2-ethylhexanoylperoxy)hexane, tert-hexylperoxy-2-ethylhexanoate, di(4-methylbenzoyl)peroxide, tert-butylperoxy-2-ethylhexanoate, di(3-methylbenzoyl)peroxide, benzoyl(3-methylbenzoyl)peroxide, dibenzoyl peroxide, dibenzoyl peroxide, 1,1-di(tert-butylperoxy)-2-methylcyclohexane, 1,1-di(tert-hexylperoxy)-3,3,5-trimethylcyclohexane, 1,1-di(tert-hexylperoxy)cyclohexane, 1,1-di(tert-butylperoxy)cyclohexane, 2.2-di(4,4-di-(tert-butylperoxy)cyclohexyl)propane, tert-hexylperoxyisopropylmonocarbonate, tert-butylperoxymaleic acid, tert-butylperoxy-3,5,5-trimethylhexanoate, tert-butylperoxylaurate, tert-butylperoxyisopropylmonocarbonate, tert-butylperoxy-2-ethylhexylmonocarbonate, tert-hexylperoxybenzoate, 2,5-dimethyl-2,5-di(benzolyperoxy)hexane, tert-butylperoxyacetate, 2,2-di(tert-butylperoxy)butane, tert-butylperoxybenzoate, n-butyl-4,4-di-tert-butylperoxyvalerate, di(2-tert-butylperoxyisopropyl)benzene, dicumyl peroxide, di-tert-hexyl peroxide,2,5-dimethyl-2,5-di(tert-butylperoxy)hexane, tert-butylcumyl peroxide, di-tert-butyl peroxide, p-methanehydro peroxide, 2,5-dimethyl-2,5-di(tert-butylperoxy)hexine-3, diisopropylbenzenehydro peroxide, 1,1,3,3-tetramethylbutylhydro peroxide, cumenehydro peroxide, tert-butylhydro peroxide, 2,3-dimethyl-2,3-diphenylbutane, 2,-dichlorobenzoyl peroxide, 0-chlorobenzoyl peroxide, p-chlorobenzoyl peroxide, tris(tert-butylperoxy)triazine, 2,4,4-trimethylpentylperoxyneodecanoate, α-cumylperoxyneodecanoate, tert-amylperoxy-2-ethylhexanoate, tert-butylperoxyisobutyrate, di-tert-butylperoxyhexahydro terephthalate, di-tert-butylperoxytrimethyl adipate, di-3-methoxybutylperoxydicarbonate, diisopropylperoxydicarbonate, tert-butylperoxyisopropylcarbonate, 1,6-bis(tert-butylperoxycarbonyloxy)hexane, diethylene glycol bis(tert-butylperoxycarbonate), tert-hexylperoxyneodecanoate, and Luperox 11 commercially available from Arkema Yoshitomi, Ltd.

As the organic azo compound, preferably used are azonitrile compounds such as V-30, V-40, V-59, V-60, V-65 and V-70; azoamide compounds such as VA-080, VA-085, VA-086, VF-096, VAm-110 and VAm-111; cyclic azoamizine compounds such as VA-044 and VA-061; azoamizine compounds such as V-50, VA-057; azoester compounds such as V-601 and V-401; all commercially available from ako Pure Chemical Industries, Ltd., 2,2-azobis(4-methoxy-2,4-dimethylvaleronitrile), 2,2-azobis(2,4-dimethylvaleronitrile), 2,2-azobis(2-methylpropionitrile), 2,2-azobis(2,-dimethylbutyronitrile), 1,1-azobis(cyclohexane-1-carbonitrile), 1-[(1-cyano-1-methylethyl)azo]formamide, 2,2-azobis{2-methyl-N-[1,1-bis(hydroxymethyl)-2-hydroxyethyl]propionamide}, 2,2-azobis[2-methyl-N-(2-hydroxybutyl)propionamide], 2,2-azobis[N-(2-propenyl)-2-methylpropionamide], 2,2-azobis(N-butyl-2-methylpropionamide), 2,2-azobis(N-cyclohexyl-2-methylpropionamide), 2,2-azobis[2-(2-imidazoline-2-yl)propane]dihydrochloride, 2,2-azobis[2-(2-imidazoline-2-yl) propane]disulfate dihydrate, 2,2-azobis[2-[1-(2-hydroxyethyl)-2-imidazoline-2-yl]propane]dihydrochloride, 2,2-azobis[2-(2-imidazoline-2-yl)propane], 2,2-azobis(1-imino-1-pyrrolidino-2-methylpropane)dihydrochloride, 2,2-azobis(2-methylpropionamidine dihydrochloride, 2,2-azobis[N-(2-carboxyethyl)-2-methylpropionamidine]tetrahydrate, dimethyl-2,2-azobis(2-methyl propionate), 4,4-azobis(4-cyanovaleric acid), and 2,2-azobis(2,4,-trimethylpentane.

When the cation polymerizable compound is contained, the thermal acid generator is preferably used, and sulfonium salt is more preferably used, typically available under the trade name of San-Aid Si Series from Sanshin Chemical Industry Co. Ltd.

The amount of mixing of the heat polymerization initiator suitably used for the present invention is preferably 0.1 to 5% by mass of the total components of the underlying film composition, excluding the solvent, and more preferably 0.2 to 2.0% by mass.

### <Photo-Polymerization Initiator>

In the present invention, a photo-polymerization initiator may be contained for the purpose of initiating crosslinking.

The radical photo-polymerization initiator used in the present invention is selectable typically from those commercially available. Those described for example in paragraph [0091] of JP-A-2008-105414 may preferably be used. Among them, acetophenone-based compound, acylphosphine oxide-based compound, and oxim ester-based compound are preferable from the viewpoints of curing sensitivity and absorption characteristics.

The acetophenone-base compound may preferably be exemplified by hydroxyacetophenone-base compound, dialkoxyacetophenone-base compound, and aminoacetophenone-base compound. The hydroxyacetophenone-base compound may preferably be exemplified by Irgacure (registered trademark) 2959 (1-[4-(2-hydroxyethoxy)phenyl]-2-hydroxy-2-methyl-1-propane-1-one, Irgacure (registered trademark) 184 (1-hydroxycyclohexylphenylketone), Irgacure (registered trademark) 500 (1-hydroxycyclohexylphenylketone, benzophenone), Darocur (registered trademark) 1173 (2-hydroxy-2-methyl-1-phenyl-1-propane-1-one), all of which are available from.

The dialkoxyacetophenone-base compound may preferably be exemplified by Irgacure (registered trademark) 651 (2,2-dimethoxy-1,2-diphenylethane-1-one) available from BASF GmbH.

The aminoacetophenone-base compound may preferably be exemplified by Irgacure (registered trademark) 369 (2-benzyl-2-dimethylamino-1-(4-morpholinophenyl)butanone-1), Irgacure (registered trademark) 379 (EG) (2-dimethylamino-2-(4-methylbenzyl)-1-(4-morpholine-4-yl-phenyl)butane-1-one), and Irgacure (registered trademark) 907 (2-methyl-1-[4-methylthiophenyl]-2-morpholinopropane-1-one), all of which are available from BASF GmbH.

The acylphosphine oxide-base compound may preferably be exemplified by Irgacure (registered trademark) 819 (bis(2,4,6-trimethylbenzoyl)-phenylphosphine oxide), Irgacure (registered trademark) 1800 (bis(2,6-dimethoxybenzoyl)-2,4,4-trimethyl-pentylphosphine oxide), Lucirin TPO (2,4,6-trimethylbenzoyldiphenylphosphine oxide), and Lucirin TPO-L (2,4,-trimethylbenzoylphenylethoxyphosphine oxide), all of which are available from BASF GmbH.

The oxime ester-base compound may preferably be exemplified by Irgacure (registered trademark) OXE01 (1,2-octanedione, 1-[4-(phenylthio)phenyl]-2-O-benzoyloxime)), and Irgacure (registered trademark) OXE02 (ethanone, 1-[9-ethyl-6-(2-methylbenzoyl)-9H-carbazole-3-yl]-1-(O-acetyloxime)), all of which are available from BASF GmbH.

Preferable examples of the cationic photo-polymerization initiator suitably used for the present invention include sulfonium salt compound, iodonium salt compound and oxime sulfonate compound, which are exemplified by 4-methylphenyl(4-(1-methylethyl)phenyliodonium tetrakis(pentafluorophenyl)borate (PI2074, from Rhodia Inc.), 4-methylphenyl[4-(2-methylpropyl)phenyliodonium hexafluorophosphate (Irgacure 250, from BASF), and Irgacure PAG103, 108, 121, 203 (from BASF).

In the present invention, “light” includes not only those in the wavelength regions of UV, near-UV, deep-UV, visible light and infrared, and other electromagnetic waves, but also radiation ray. The radiation ray includes microwave, electron beam, EUV and X-ray. Also laser light such as 248 nm excimer laser, 193 nm excimer laser, and 172 nm excimer laser are usable. These sorts of light may be monochromatic light obtained after being passed through an optical filter, or may be composite light composed of a plurality of light components with different wavelengths.

The amount of mixing of the photo-polymerization initiator used for the present invention is 0.1 to 5% by mass of the total components of the underlying film composition, excluding the solvent, and more preferably 0.2 to 2.0% by mass.

### <Polymerization Inhibitor>

The underlay film composition of the present invention further preferably contains a polymerization inhibitor.

The content of the polymerization inhibitor is from 0.001 to 1% by mass, more preferably from 0.005 to 0.5% by mass, and even more preferably from 0.008 to 0.05% by mass, relative to all the polymerizable monomers in the composition, and the change in the viscosities over time can be inhibited while maintaining a high curing sensitivity by blending the polymerization inhibitor in an appropriate amount. The polymerization inhibitor may be added at the production of the polymerizable monomer or may be added the curable composition after the production, of the polymerizable monomer.

The polymerization inhibitor suitably used for the present invention is exemplified by hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-tert-butylphenol), cerous N-nitrosophenylhydroxylamine, phenothiazine, phenoxazine, 4-methoxynaphthol, 2,2,6,6-tetramethylpiperidine-1-oxyl, free radical, 2,2,6,6-tetramethylpiperidine, 4-hydroxy-2,2,6,6-tetramethylpiperidine-1-oxyl, free radical, nitrobenzene, and dimethylaniline. Among them, phenothiazine, 4-methoxynaphthol, 2,2,6,6-tetramethylpiperidine-1-oxyl, free radical, 2,2,6,6-tetramethylpiperidine, and 4-hydroxy-2,2,6,6-tetramethylpiperidine-1-oxyl, free radical are preferable, since they exhibit effects even under an anaerobic condition.

### <Catalyst>

The underlying film composition of the present invention may contain a catalyst. The catalyst is exemplified by p-toluenesulfonic acid and derivative thereof, such as Cycat 4040 and 4045 (from Cytec Industries, Inc.). Other examples include mineral acids such as hydrochloric acid, phosphoric acid and nitric acid; amine salts thereof; carboxylic acids; and amine salts thereof.

The amount of mixing of the catalyst in the underlying film composition of the present invention is preferably 0.05 to 50% by mass of the total components, excluding the solvent, and more preferably 0.1 to 5.0% by mass.

The underlay film composition of the present invention may be prepared by mixing the individual components described in the above. After mixing the individual components, the mixture is preferably filtered typically through a filter with a pore size of 0.003 μm to 5.0 μm. The filtration may be proceeded according to a multi-step scheme or may be repeated multiple times. The filtrate may be re-filtered. Examples of material for composing the filter used for the filtration include polyethylene resin, polypropylene resin, fluorine-containing resin, and nylon resin, although not specifically limited.

### <Curable Composition for Imprints>

The curable composition for imprints used in combination with the underlay film composition of the present invention generally contains a polymerizable compound (C) and a polymerization initiator (D).

### Polymerizable Compound (C)

While species of the polymerizable compound used for the curable composition for imprints in the present invention is not specifically limited so long as it does not departs from the spirit of the present invention, preferable examples include polymerizable unsaturated monomer having 1 to 6 ethylenic unsaturated bond-containing group; epoxy compound and oxetane compound; vinyl ether compound; styrene derivative; and propenylether or butenyl ether. The curable composition for imprints preferably has a polymerizable group capable of polymerizing with a polymerizable group on the underlay film composition for imprints. Among them, (meth)acrylate is preferable. Specific examples of these compounds are exemplified by those described in paragraphs [0020] to [0098] of JP-A-2011-231308, the contents of which are incorporated by reference into this specification.

As the polymerizable compound, preferably contained is a polymerizable compound having an alicyclic hydrocarbon group and/or aromatic group, and, more preferably contained are both of the polymerizable compound having an alicyclic hydrocarbon group and/or aromatic group, and a polymerizable compound having containing silicon atom and/or fluorine atom. It is further preferable that the total mass of the polymerizable compounds having an alicyclic hydrocarbon group and/or aromatic group, out of all polymerizable components contained in the curable composition for imprints of the present invention, is 30 to 100% by mass relative to the total polymerizable compounds, more preferably 50 to 100% by mass, and still more preferably 70 to 100% by mass.

In a more preferable embodiment, as the polymerizable compound, the (meth)acrylate polymerizable compound containing aromatic group preferably accounts for 50 to 100% by mass of the total polymerizable components, more preferably 70 to 100% by mass, and particularly 90 to 100% by mass. In a particularly preferable embodiment, a polymerizable compound (1) described below accounts for 0 to 80% by mass of the total polymerizable components (more preferably 20 to 70% by mass) a polymerizable compound (2) described below accounts for 20 to 100% by mass of the total polymerizable components (more preferably 50 to 100% by mass), and a polymerizable compound (3) described below accounts for 0 to 10% by mass of the total polymerizable components (more preferably 0.1 to 6% by mass).

(1) Polymerizable compound having an aromatic group (preferably phenyl group or naphthyl group, and more preferably naphthyl group) and a (meth)acrylate group;
(2) polymerizable compound having an aromatic group (preferably phenyl group or naphthyl group, and more preferably phenyl group) and two (meth)acrylate groups; and
(3) polymerizable compound having at least either one of fluorine atom and silicon atom, and a (meth)acrylate group.

In the curable composition for imprints, content of the polymerizable compound having a viscosity at 25° C. of smaller than 5 mP·s is 50% by mass or less, relative to the total polymerizable compound, more preferably 30% by mass or less, and still more preferably 10% by mass or less. By adjusting the content to the above-described ranges, stability of discharge of ink in the ink jet process may be improved, and transfer failure in imprinting may be reduced.

### Polymerization Initiator (D)

In the curable composition for imprints used in the present invention, a photo-polymerization initiator is contained. The photo-polymerization initiator used in the present invention may be any compound which generates an active species capable of polymerizing the above-described polymerizable compound under photoirradiation. The photo-polymerization initiator is preferably a radical polymerization initiator or cationic polymerization, and the radical polymerization initiator is more preferable. In the present invention, a plurality of species of photo-polymerization initiator may be used.

The content of the photo-polymerization initiator to be in all of the component except for solvents in the composition of the invention may be, for example, from 0.01 to 15% by mass of all the polymerizable monomers constituting the composition, preferably from 0.1 to 12% by mass, more preferably from 0.2 to 7% by mass. In case where two or more different types of photo-polymerization initiators are used, the total amount thereof falls within the above range. When the content of the photo-polymerization initiator is at least 0.01% by mass, then it is favorable since the sensitivity (rapid curability), the power of resolution, the line edge accuracy and the coating film strength of the composition tend to be better. On the other hand, when the content of the photopolymerization initiator is at most 15% by mass, it is also favorable since the light transmittance, the discoloration resistance and the handlability of the composition tend to be better.

The radical photo-polymerization initiator usable in the present invention is exemplified by those mixable to the underlying film composition, enumerated in the paragraph above under the title of Photo-Polymerization Initiator.

### —Surfactant—

The curable composition for imprints used in the present invention preferably contains a surfactant. The surfactant usable in the present invention is exemplified by those described above in connection with the underlying film composition. Content of the surfactant used in the present invention is preferably 0.001 to 5% by mass, for example, of the whole components, preferably 0.002 to 4% by mass, and more preferably 0.005 to 3% by mass. For the case where two or more species of surfactant are used, the total content of which falls in the above-described ranges. When the content of surfactant is adjusted to the range from 0.001 to 5% by mass of the composition, a good effect of ensuring uniformity in coating may be obtained, while preventing degradation of mold transferability due to excess of surfactant.

The surfactant is exemplified by those which may be contained in the underlying film composition described above.

### —Antioxidant—

Preferably, the curable composition for imprints used in the invention contains a known antioxidant. The content of the antioxidant to be in the composition is, for example, from 0.01 to 10% by mass of the total amount of the polymerizable monomers constituting the composition, preferably from 0.2 to 5% by mass. When two or more different types of antioxidants are in the composition, the total amount thereof falls within the above range.

The antioxidant is for preventing fading by heat or photoirradiation, and for preventing fading by various gases such as ozone, active hydrogen NOx, SOx (x is an integer), etc. Especially in the invention, the antioxidant added to the composition brings about the advantage that the cured film is prevented from being discolored and the film thickness is prevented from being reduced through decomposition. The antioxidant includes hydrazides, hindered amine-type antioxidants, nitrogen-containing heterocyclic mercapto compounds, thioether-type antioxidants, hindered phenol-type antioxidants, ascorbic acids, zinc sulfate, thiocyanates, thiourea derivatives, saccharides, nitrites, sulfites, thiosulfates, hydroxylamine derivatives, etc. Of those, preferred are hindered phenol-type antioxidants and thioether-type antioxidants from the viewpoint of their effect of preventing cured film discoloration and preventing film thickness reduction.

Commercial products of the antioxidant usable herein include Irganox 1010, 1035, 1076, 1222 (all by BASF GmbH); Antigene P, 3C, FR, Sumilizer S, Sumilizer GA80 (by Sumitomo Chemical); Adekastab A070, A080, A0503 (by Adeka), etc. These may be used either singly or as combined.

### —Polymerization Inhibitor—

Furthermore, the curable composition for imprints used in the invention preferably comprises a polymerization inhibitor. The content of the polymerization inhibitor is from 0.001 to 1% by mass, more preferably from 0.005 to 0.5% by mass, and even more preferably from 0.008 to 0.05% by mass, relative to all the polymerizable monomers, and the change in the viscosities over time can be inhibited while maintaining a high curing sensitivity by blending the polymerization inhibitor in an appropriate amount. The polymerization inhibitor may be added at the production of the polymerizable monomer or may be added the curable composition for imprints after the production of the polymerizable monomer.

The polymerization inhibitor suitably used for the present invention is preferably exemplified by those described above in connection with the underlying film composition.

### —Solvent—

A solvent may be used for the curable composition for imprints used in the invention, in accordance with various needs. Preferably, the solvent has a boiling point at normal pressure of from 80 to 200° C. Regarding the type of the solvent, any solvent capable of dissolving the composition may be used. Preferred are solvents having at least any one of an ester structure, a ketone structure, a hydroxyl group and an ether structure. Concretely, the solvent is preferably one or more selected from propylene glycol monomethyl ether acetate, cyclohexanone, 2-heptanone, gamma-butyrolactone, propylene glycol monomethyl ether, ethyl lactate. Most preferred is a solvent containing propylene glycol monomethyl ether acetate as securing coating uniformity.

The content of the solvent in the composition for imprints used in the present invention may be suitably optimized depending on the viscosity of the constitutive ingredients except the solvent, the coatability of the composition and the intended thickness of the film to be formed. From the viewpoint of the coatability, the solvent content is preferably 99% or less by mass of the composition. For the case where the curable composition for imprints used in the present invention is applied onto the base by the ink jet process, it is preferable that the solvent is substantially not contained (for example, 3% by mass or less). On the other hand, when a pattern having a film thickness of 500 nm or less is formed by spin-coating method or the like, the content may be 20 to 99% by mass, preferably 40 to 99% by mass, specifically preferably 70 to 98% by mass.

### —Polymer Ingredient—

The curable composition for imprints used in the invention may contain a poly-functional oligomer having a larger molecular weight than that of the above-mentioned, other poly-functional monomer within a range capable of attaining the object of the invention, for the purpose of further increasing the crosslinking density of the composition. Examples of the photoradical-polymerizable poly-functional oligomer include various acrylate oligomers such as polyester acrylates, urethane acrylates, polyether acrylates, epoxy acrylates. The amount of the oligomer ingredient to be added to the composition may be preferably from 0 to 30% by mass of the composition except the solvent therein, more preferably from 0 to 20% by mass, even more preferably from 0 to 10% by mass, most preferably from 0 to 5% by mass.

The curable composition for imprints for imprints used in the present invention may further contain a polymer component, in view of improving the dry etching resistance, imprint suitability and curability. The polymer component preferably has a polymerizable functional group in the side chain thereof. Weight-average molecular weight of the polymer component is preferably 2,000 to 100,000, and more preferably 5,000 to 50,000, in view of compatibility with the polymerizable monomer. Amount of addition of the polymer component, with respect to portion of the composition excluding the solvent, is preferably 0 to 30% by mass, more preferably 0 to 20% by mass, and most preferably 2% by mass or less. Pattern formability may be improved by adjusting the content of polymer component having a molecular weight of 2,000 or larger is 30% by mass or less, with respect to the portion of the curable composition for imprints of the present invention excluding the solvent. From the viewpoint of pattern formability, as least as possible amount of resin component is preferable, and therefore the curable composition preferably contains no polymer component other than those composing the surfactant or trace amounts of additives.

The curable composition for imprints used in the present invention may optionally be added, besides the above-described components, with mold releasing agent, silane coupling agent, UV absorber, photo-stabilizer, anti-aging agent, plasticizer, adherence promoter, heat polymerization initiator, colorant, elastomer particle, photo-acid amplifier, photo-base generator, basic compound, fluidity controlling agent, defoaming agent, or dispersion aid.

The curable composition for imprints used in the present invention may be prepared by mixing the individual components described in the above. The curable composition is mixed and dissolved generally in the temperature range from 0° C. to 100° C. After the mixing, the mixture is preferably filtered through a filter having a pore size of 0.003 μm to 5.0 μm for example. The filtration may be proceeded according to a multi-step scheme or may be repeated multiple times. The filtrate may be re-filtered. Examples of material for composing the filter used for the filtration include polyethylene resin, polypropylene resin, fluorine-containing resin, and nylon resin, although not specifically limited.

The curable composition for imprints used in the present invention is preferably configured so that a mixed solution of the whole components excluding the solvent shows a viscosity of 100 mPa·s or smaller, more preferably 1 to 70 mPa·s, still more preferably 2 to 50 mPa·s, and most preferably 3 to 30 mPa·s.

The curable composition for imprints used in the present invention is bottled, after being manufactured, into a container such as gallon bottle or coated bottle, and transported and stored. In this case, the inner space of the container may be replaced with inert nitrogen, argon or the like, for the purpose of preventing degradation. While the curable composition for imprints may be transported and stored at normal temperature, the temperature may also be controlled in the range from −20° C. to 0° C. in order to prevent denaturation. Of course, it is preferably shielded from light to a degree enough to prevent reaction.

A permanent film (resist used as structural component) to be remained for use in liquid crystal display device (LCD), and a resist used for processing of the substrate composed of electronic materials are strongly required to avoid contamination by ionic impurities such as metals and organic substances, so that operations of the product will not be interfered. For this purpose, concentration of the ionic impurities such as metals or organic substances in the curable composition for imprints of the present invention is preferably suppressed to 1 ppm or below, more preferably 100 ppb or below, and still more preferably 10 ppb or below.

### <Method of Forming Film>

The underlay film composition of the present invention is applied onto the substrate to form an underlay film. Methods of application onto the substrate include dip coating, air knife coating, curtain coating, wire bar coating, gravure coating, extrusion coating, spin coating, slit scanning, and ink jet process, by which a coated film or liquid droplets are formed on the substrate. From the viewpoint of uniformity of thickness, coating process is preferable, and spin coating is more preferable. The solvent is then dried off. Preferable drying temperature is 70° C. to 130° C. The drying is preferably followed by curing with the aid of activation energy (preferably heat and/or light). It is preferable to proceed the curing under heating at 150° C. to 250° C. The drying-off of the solvent and the curing may be proceeded at the same time. As described above, it is preferable in the present invention to apply the underlying film composition, to partially cure the underlying film composition by heating or photo-irradiation, and to apply the composition for imprints. By employing such means, also the underlying film composition will completely cure in the process of photo-curing of the curable composition for imprints, and thereby the adhesiveness will tend to improve.

Thickness of the underlay film composed of the composition of the present invention may vary depending on applications, and it falls in the range approximately from 0.1 nm to 100 nm, preferably from 0.5 to 20 nm, more preferably from 1 to 10 nm. The underlay film composition of the present invention may be coated multiple times. The obtained underlay film is preferably smooth as possible.

### <Base>

The substrate (base or support), on which the underlay film composition for imprints of the present invention, is coated is selectable depending on various applications, typically from quartz, glass, optical film, ceramic material, evaporated film, magnetic film, reflective film, metal substrates composed of Ni, Cu, Cr or Fe, paper, SOG (Spin On Glass), polymer substrates composed of polyester film, polycarbonate film, or polyimide film, TFT array substrate, electrode plates of PDF, glass or transparent plastic substrate, electro-conductive substrate made of ITO or metal, insulating substrate, and substrates used for manufacturing semiconductor devices composed of silicon, silicon nitride, polysilicon, silicon oxide or amorphous silicon, without special limitation. Nevertheless, if intended for etching, the base is preferably a base for semiconductor process as described later.

The stacked article of the present invention, composed of the substrate, and the pattern formed by the underlay film for imprints and the curable composition for imprints, may be used as an etching resist. The base of this case is exemplified by a base (silicon wafer) having formed thereon a film of SiO₂ or silicon nitride.

A plurality of bases may be etched at the same time. The stacked article of the present invention, composed of the substrate, and the pattern formed by the underlay film for imprints and the curable composition for imprints, is useful as a permanent film to be remained in devices or structures, in its intact form, or in the form obtained after removal of the films remained in the recess, or in the form obtained after removal of the underlay film, since the stacked article is less likely to cause separation of film under variable environment or stress.

In particular in the present invention, a base having a polar group exposed to the surface is preferably used. By using the base having a polar group exposed to the surface, the adhesiveness with the underlying film composition will tend to improve. The polar group is exemplified by hydroxy group, carboxy group, and silanol group. Silicon base and quartz base are particularly preferable.

Also geometry of the substrate is not specifically limited, and may be given in the form of sheet or roll. The mold in the roll form is adopted when continuity in production is required for pattern transfer.

### <Process>

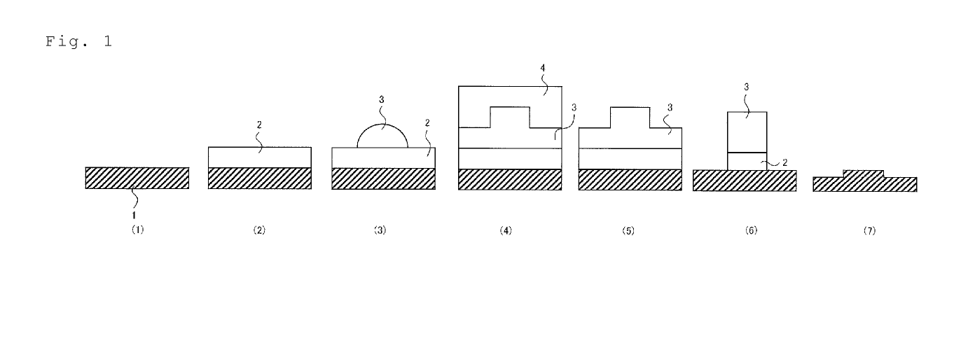

FIG. 1 is a schematic drawing illustrating an exemplary process of manufacturing involving etching of the substrate, wherein reference numeral 1 denotes the substrate, 2 denotes the underlay film, 3 denotes the curable composition fox imprints, and 4 denotes the mold. As seen in FIG. 1, the underlay film composition 2 is applied onto the surface of the substrate 1 (2), the curable composition for imprints 3 is applied onto the surface (3), and the mold is applied onto the surface (4). After photo-irradiation, the mold is separated (5). The etching is conducted conforming to the resultant pattern composed of the curable composition for imprints (6). The curable composition for imprints 3 and the underlay film composition 2 are then separated, to thereby obtain the substrate having a desired pattern formed therein (7). In this process, adhesiveness between the substrate 1 and the curable composition for imprints 3 is important, since poor adhesiveness prevents the pattern of the mold 4 from being exactly transferred.

### [Pattern Forming Method]

A pattern forming method (pattern transfer method) using the curable composition for imprints will be detailed below.

The pattern forming method of the present invention includes:

applying the underlying film composition for imprints of the present invention on a base, to form an underlying film;

applying a curable composition for imprints onto the underlying film;

curing the curable composition for imprints by photo-irradiation while keeping the curable composition for imprints and the underlying film held between the base and a mold with a fine pattern; and

releasing the mold.

It is further preferable to apply the curable composition for imprints, after applying the underlying film composition for imprints onto the base, and after curing a part of the underlying film composition for imprints by heating or photo-irradiation.

Methods of applying the curable composition for imprints of the present invention onto the underlay film is arbitrarily selectable from those publicly known. The methods of application include dip coating, air knife coating, curtain coating, wire bar coating, gravure coating, extrusion coating, spin coating, slit scanning, and ink jet process, by which a coated film or liquid droplets are formed on the underlay film. Thickness of the pattern forming layer composed of the curable composition for imprints used in the present invention is approximately 0.03 μm to 30 μm, which may vary depending on applications. The curable composition for imprints may be coated according to a multiple-coating scheme. In a method of forming liquid droplets onto the underlay film typically by ink jet process, liquid droplets preferably has a volume of approximately 1 pl to 20 pl, and are arranged on the underlay film while being spaced from each other.

Next, in the patterning method of the invention, a mold is pressed against the surface of the patterning layer for transferring the pattern from the mold onto the patterning layer. Accordingly, the micropattern previously formed on the pressing surface of the mold is transferred onto the patterning layer.

Alternatively, the composition for imprints may be coated over the mold having a pattern formed thereon, and the under layer film may be pressed thereto.

Next, the mold material adoptable to the present invention will be explained. For photonanoimprint lithography using the curable composition for imprints, a light-transmissive material is selected for composing at least either one of the mold and substrate. In the photoimprinting lithography adopted to the present invention, the curable composition for imprints is coated over the substrate to form the pattern forming layer, the light-transmissive mold is pressed to the surface thereof, and light is irradiated from the back side of the mold to thereby cure the pattern forming layer. Alternatively, the curable composition for imprints may be coated over the light-transmissive substrate, the mold may be pressed thereto, and light may be irradiated from the back side of the substrate to thereby cure the curable composition for imprints. The photoirradiation may be conducted while keeping the mold in contact or after releasing the mold. The photoirradiation with the mold kept in contact is preferred in the present invention.

The mold adoptable to the present invention has a pattern to be transferred. The pattern on the mold may be formed typically by photolithography, electron beam lithography or the like, depending on a desired level of process accuracy, without limiting methods of forming the mold pattern. Alternatively, a pattern formed by the pattern formation method of the present invention may be used as a mold.

Materials for composing the light-transmissive mold used in the present invention are arbitrarily selectable from those having predetermined levels of strength and durability, without special limitation. Specific examples thereof include glass, quartz, light-transmissive resins such as PMMA and polycarbonate resin, transparent metal evaporated film, flexible film such as polydimethyl siloxane, photo-cured film and metal film.

Non-light-transmissive mold materials, adoptable to the present invention when the light-transmissive substrate is used, are arbitrarily selectable from those having predetermined levels of strength, without special limitation. Specific examples thereof include ceramic material, evaporated film, magnetic film, reflective film, metal substrates composed of Ni, Cu, Cr or Fe, and substrates composed of SiC, silicon, silicon nitride, polysilicon, silicon oxide or amorphous silicon, without special limitation. Also geometry of the substrate is not specifically limited, and may be given in the form of sheet or roll. The mold in the roll form is adopted when continuity in production is required for pattern transfer.

The mold used in the pattern formation method of the present invention may be treated with a mold releasing agent, aiming at improving separability between the curable composition for imprints and the mold surface. Examples of this sort of mold include those treated with a silicone-based or fluorine-containing silane coupling agent, also commercially available under the trade name of Optool DSX from Daikin Industries Ltd., and Novec EGC-1720 from Sumitomo 3M Ltd.

When the curable composition for imprints is used in photoimprinting lithography, the pattern formation method of the present invention is preferably conducted under a mold pressure of 10 atm or below. By adjusting the mold pressure to 10 atm or below, there are tendencies of suppressing deformation of the mold and substrate, and improving the pattern accuracy. The low pressure is preferable also in terms of possibility of downsizing the apparatus. The mold pressure is selectable within the range capable of ensuring uniformity in the mold transfer, when observed in a region of the curable composition for imprints thinned under projected portions of the mold.

In the pattern formation method of the present invention, energy of photoirradiation in the process of irradiating light to the pattern forming layer is good enough if it is sufficiently larger than a level energy required for curing. The level of energy of irradiation required for curing is appropriately determined, by analyzing consumption of the unsaturated bonds of the curable composition for imprints and tackiness of the cured film.

In the photoimprinting lithography adoptable to the present invention, while the photoirradiation is generally conducted while keeping the substrate to normal temperature, the photoirradiation may also be conducted under heating in order to enhance the reactivity. Also the photoirradiation in vacuo is preferable, since vacuum established prior to the photoirradiation is effective in preventing entrainment of bubbles, suppressing lowering in the reactivity due to invasion of oxygen, and enhancing adhesiveness between the mold and the curable composition for imprints. In the pattern formation method of the present invention, a preferable degree of vacuum in the photoirradiation is in the range from 10⁻¹ Pa to normal pressure.

Light to be used for photoirradiation to cure the curable composition for imprints of the invention is not specifically defined. For example, it includes light and irradiations with a wavelength falling within a range of high-energy ionizing radiation, near-ultraviolet, far-ultraviolet, visible, infrared, etc. The high-energy ionizing radiation source includes, for example, accelerators such as Cockcroft accelerator, Handegraf accelerator, linear accelerator, betatoron, cyclotron, etc. The electron beams accelerated by such an accelerator are used most conveniently and most economically; but also are any other radioisotopes and other radiations from nuclear reactors, such as gamma rays, X rays, a rays, neutron beams, proton beams, etc. The UV sources include, for example, UV fluorescent lamp, low-pressure mercury lamp, high-pressure mercury lamp, ultra-high-pressure mercury lamp, xenon lamp, carbon arc lamp, solar lamp, etc. The radiations include microwaves, EUV, etc. In addition, laser rays for use in microprocessing of semiconductors, such as LED, semiconductor laser ray, 248 nm KrF excimer laser ray, 193 nm ArF excimer laser ray and others, are also favorably used in the invention. These lights may be monochromatic lights, or may also be lights of different wavelengths (mixed lights).

In photoexposure, the light intensity is preferably within a range of from 1 mW/cm² to 50 mW/cm². When the light intensity is at least 1 mW/cm², then the producibility may increase since the photoexposure time may be reduced; and when the light intensity is at most 50 mW/cm², then it is favorable since the properties of the permanent film formed may be prevented from being degraded owing to side reaction. Also preferably, the dose in photoexposure is within a range of from 5 mJ/cm² to 1000 mJ/cm². When the dose is less than 5 mJ/cm², then the photoexposure margin may be narrow and there may occur problems in that the photocuring may be insufficient and the unreacted matter may adhere to mold. On the other hand, when the dose is more than 1000 mJ/cm², then the composition may decompose and the permanent film formed may be degraded.

In the patterning method of the invention, after the pattern layer (a layer comprising the curable composition for imprints layer) is cured through photoirradiation, if desired, the cured pattern may be further cured under heat given thereto. The method may additionally include the post-curing step. Thermal curing of the composition of the invention after photoirradiation is preferably attained at 150 to 280° C., more preferably at 200 to 250° C. The heating time is preferably from 5 to 60 minutes, more preferably from 15 to 45 minutes.

The patterned stacked article of the present invention, composed of the substrate, the underlay film for imprints, and the curable composition for imprints, may be used as a permanent film (resist used as structural components) used for liquid crystal display (LCD) and so forth.

### Example

The characteristics of the invention are described more concretely with reference to Production Examples and Examples given below. In the following Examples, the material used, its amount and the ratio, the details of the treatment and the treatment process may be suitably modified or changed not overstepping the scope of the invention. Accordingly, the invention should not be limitatively interpreted by the Examples mentioned below.

The curable main components listed in Table 1 below were mixed according to the ratios of mixing listed in Table 2, and dissolved in propylene glycol monomethylether acetate to prepare a 0.1% by mass solution. The solution was filtered through a 0.1 μm tetrafluoroethylene filter to obtain each underlying film composition. The thus-obtained underlying film composition was spin-coated over a silicon wafer, heated on a hot plate at 100° C. for one minute to dry off the solvent. The product was further heated at 220° C. for 5 minutes to partially cure, to form an underlying film. The thickness after curing was found to be 3 nm. In Tables below, the values are given in parts by mass.

TABLE 1

| | Curable main component | Manufactured by |
|---|---|---|
| A1 | Polyethylene glycol 600 | Wako |
| | | Pure Chemical |
| | | Industries, Ltd. |
| A2 | 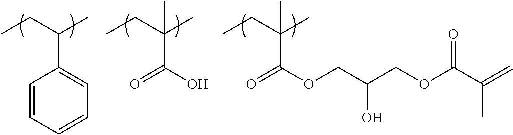 Molar ratio of repeating units = 40/30/30 | Styrene/methacrylic acid copolymer reacted with glycidyl methacrylate |
| A3 | 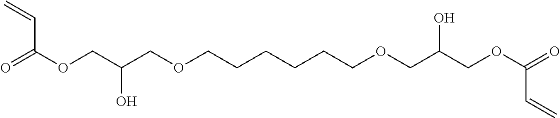 [SMILES: C=CC(=O)OCC(O)COCCCCCCOCC(O)COC(=O)C=C] | |
| A4 | 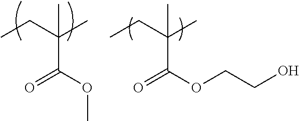 Molar ratio of repeating units = 60/40 | |
| A5 | 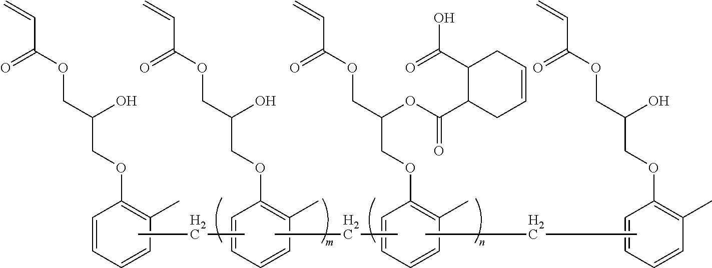 Average m + n = 4 Average n/(m + n) = 0.5 | NK Oligc EA-7140/ PGMAc, from Shin-Nakamura Chemical Co., Ltd. |

TABLE 2

| | | Manufactured |
|---|---|---|
| | Crosslinking agent | by |
| K1 | 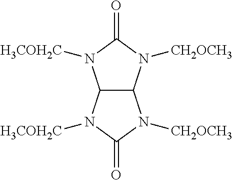 | Nikalac MX-270, from Sanwa Chemical Co., Ltd. |
| K2 | 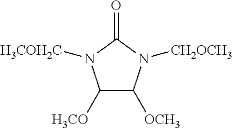 | Nikalac MX-280, from Sanwa Chemical Co., Ltd. |
| K3 | 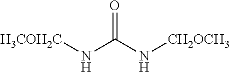 | Nikalac MX-290, from Sanwa Chemical Co., Ltd. |
| K4 | 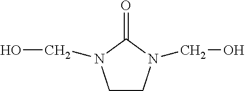 | |
| K5 | 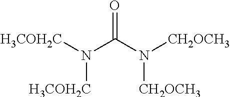 | |
| Comparative | Methyl etherified melamine | Cymel 301, |
| 1 | resin | from Cytec |
| | | Industries |
| | | Inc. |
| Comparative | Methyl etherified melamine | Cymel 303ULF, |
| 2 | resin | from Cytec |
| | | Industries |
| | | Inc. |
| Comparative | Methyl etherified melanine | Cymel 350, |
| 3 | resin | from Cytec |
| | | Industries |
| | | Inc. |
| Comparative | Benzoguanamine resin | Nikalac |
| 4 | | BX-4000, from |
| | | Sanwa Chemical |
| | | Co., Ltd. |
| Comparative | Benzoguanamine resin | Cymel 1123, |
| 5 | | from Cytec |
| | | Industries |
| | | Inc. |

TABLE 3

| | Underlying film | | | | | | | | | | | | | | |
|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 |
| A1 | 10 | | | | | | | | | | | | | | |
| A2 | | 40 | | | | | | | | | | | | | |
| A3 | 70 | | 40 | | | | 40 | | | 40 | | 40 | | | |
| A4 | | | 40 | 80 | | | 40 | 80 | | 40 | | 40 | | | |
| A5 | | 40 | | | 80 | 80 | | | 80 | | 80 | | 80 | | 100 |
| K1 | 20 | 20 | 20 | 20 | | | | | | | | | | | |
| K2 | | | | | 20 | | | | | | | | | | |
| K3 | | | | | | 20 | 20 | | | | | | | | |
| K4 | | | | | | | | 20 | | | | | | | |
| K5 | | | | | | | | | 20 | | | | | | |
| Comparative 1 | | | | | | | | | | 20 | | | | | |
| Comparative 2 | | | | | | | | | | | 20 | | | | |
| Comparative 3 | | | | | | | | | | | | 20 | | | |
| Comparative 4 | | | | | | | | | | | | | 20 | | |
| Comparative 5 | | | | | | | | | | | | | | 20 | |

### <Curable Composition for Imprints>

Polymerizable monomers, polymerization initiator and additives were mixed according to the formulations listed in Table below, and 200 ppm (0.02% by mass), relative to the polymerizable monomers, of 4-hydroxy-2,2,6,6-tetramethylpiperidine-1-oxyl, free radical (from Tokyo Chemical Industry Co., Ltd.) was added as a polymerization inhibitor. The mixture was filtered through a 0.1 μm tetrafluoroethylene filter, to prepare each curable composition for imprints. The values in Table are given in percentage by weight.

TABLE 4

| | B1 | B2 | B3 | B4 | B5 | B6 |
|---|---|---|---|---|---|---|
| R-1 | 50 | | | | | |
| R-2 | | | | 50 | | |
| R-3 | | | 100 | 49.5 | | 50 |
| R-4 | | 50 | | | | |
| R-5 | 49 | 50 | | | | |
| R-6 | | | | | 100 | 50 |
| R-7 | 1 | | | 0.5 | | |
| P-1 | 2 | 2 | | | 3 | 3 |
| P-2 | | | 3 | 3 | | |
| X1 | 1 | 1 | 1 | | 1 | 1 |
| X2 | | | 2 | 2 | | |

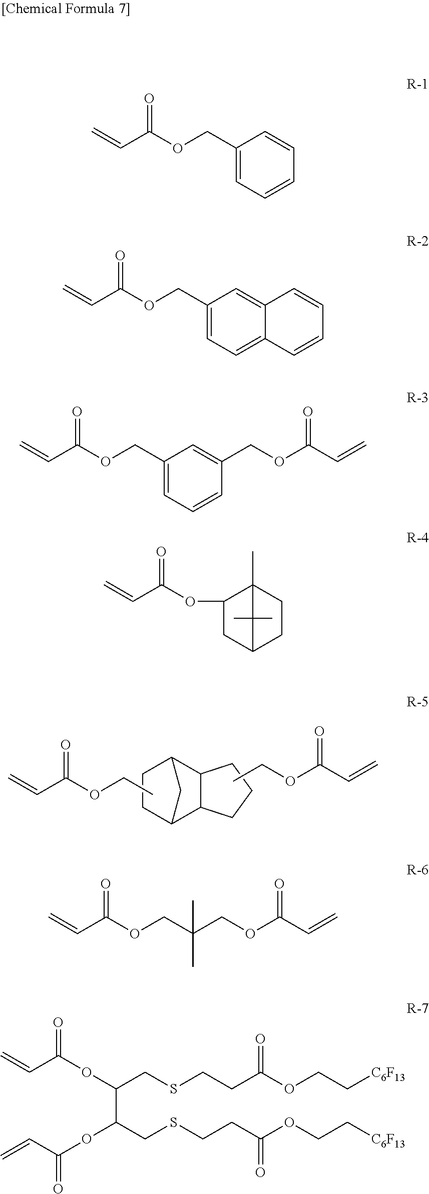

TABLE 5

| | |
|---|---|
| R-1 | Benzyl acrylate (Biscoat #160, from Osaka |
| | Organic Chemical Industry Ltd.) |
| R-2 | Synthesized from 2-bromomethylnaphthalene and |
| | acrylic acid by a general method. |
| R-3 | Synthesized from α,α′-dichloro-m-xylene and |
| | acrylic acid by a general method. |
| R-4 | IBXA, from Osaka Organic Chemical Industry Ltd. |
| R-5 | A-DCP, from Shin-Nakamura Chemical Co., Ltd. |
| R-6 | A-NPG, from Shin-Nakamura Chemical Co., Ltd. |
| R-7 | Synthesized by a method described in |
| | JP-A-2010-239121. |

### <Photo-Polymerization Initiator>

P-1: 2-Hydroxy-2-methyl-1-phenyl-1-propane-1-one (Darocur 1173, from BASF)
P-2: (2-Dimethylamino-2-(4-methylbenzyl)-1-(4-morpholine-4-ylphenyl)butane-1-one (Irgacure 379EG, from BASF)

### <Additives>

X1: PF-636 (fluorine-containing surfactant, from Omnova Solutions Inc.)
X2: Polypropylene glycol, from Wako Pure Chemical Industries, Ltd.

### <Evaluation of Separation Failure>

A quartz mold having a rectangular (1/1) line-and-space pattern with a line width of 60 nm, a groove width of 100 nm, and a line edge roughness of 3.5 nm was used as a mold.

On the thus-obtained underlying film, each photo-curable composition for imprints was dispensed using an ink jet printer DMP-2831 from FUJIFILM Dimatix, in volume of 1 pl per nozzle, while regulating time of dispensing so as to form dots at interval's of approximately 100 μm arrayed in a square matrix, so that the residual pattern will have a thickness of 15 nm. The temperature of the dispensed curable composition was adjusted to 25° C. The mold was placed thereon under a nitrogen gas flow, to thereby allow the curable composition to fill up the mold, and the stack was exposed to light of 300 mJ/cm² using a high-pressure mercury lamp illuminated from the mold side. After the exposure, the mold was released, to obtain a pattern.

The pattern was observed under an optical microscope to evaluate the separation failure:

A: good pattern obtained over the entire surface;
B: separation failure partially observed, only with a ratio of failure of less than 50% of the total area; and
C: separation failure observed in 50% or more of the total area.

### <Evaluation of Adhesiveness>

Independently from the formation of pattern described above, a silicon wafer and a quartz wafer were obtained, and the underlying film was formed on each of the waters. The curable composition for imprints was dispensed onto the silicon wafer according to a method same as described above in “Pattern Forming Method”, the quartz wafer was placed thereon, and the stack was exposed to light of 300 mJ/cm² using a high-pressure mercury lamp illuminated from the quartz wafer side. After the exposure, the quartz wafer was released, and the force of release at that time was measured.

The force of release represents the adhesiveness between the silicon wafer and the curable composition for imprints.

a: adhesiveness ≧30 N
b: 30 N> adhesiveness ≧20 N
c: 20 N> adhesiveness

TABLE 6

| | Underlying | Curable | Separation | Adhesiveness |
|---|---|---|---|---|
| | film | composition | failure | [N] |
| Example 1 | Underlying | B1 | A | a |
| | film 1 | | | |
| Example 2 | Underlying | B2 | A | a |
| | film 2 | | | |
| Example 3 | Underlying | B3 | A | a |
| | film 3 | | | |
| Example 4 | Underlying | B4 | A | a |
| | film 4 | | | |
| Example 5 | Underlying | B3 | A | a |
| | film 5 | | | |
| Example 6 | Underlying | B3 | A | a |
| | film 6 | | | |
| Example 7 | Underlying | B4 | A | a |
| | film 7 | | | |
| Example 8 | Underlying | B5 | A | a |
| | film 8 | | | |
| Example 9 | Underlying | B6 | A | a |
| | film 9 | | | |
| Example 10 | Underlying | B3 | A | a |
| | film 9 | | | |
| Comparative | Underlying | B3 | B | b |
| Example 1 | film 10 | | | |
| Comparative | Underlying | B4 | B | b |
| Example 2 | film 11 | | | |
| Comparative | Underlying | B3 | B | b |
| Example 3 | film 11 | | | |
| Comparative | Underlying | B3 | B | b |
| Example 4 | film 12 | | | |
| Comparative | Underlying | B3 | B | b |
| Example 5 | film 13 | | | |
| Comparative | Underlying | B3 | B | b |
| Example 6 | film 14 | | | |
| Comparative | Underlying | B3 | B | c |
| Example 7 | film 15 | | | |
| Comparative | No | B3 | C | c |
| Example 8 | underlying | | | |
| | film | | | |

As clearly known from Table above, the separation failure was less observed, and good adhesiveness with the base was observed when the underlying film compositions of the present invention were used. In contrast, the separation failure was more observed and the adhesiveness degraded when the underlying film compositions of Comparative Examples were used or when the underlying film was not used.

Similar results were obtained in the individual Examples, when the light source for curing the curable composition was altered from the high-pressure mercury lamp to LED, metal halide lamp, or excimer lamp.

Again similar results were obtained in the individual Examples, when the base used for measuring the adhesiveness was altered from the silicon wafer to the quartz wafer.

### REFERENCE SIGNS LIST

1 base
2 underlying film
3 curable composition for imprints
4 mold

1. An underlying film composition for imprints comprising a curable main component and a urea-based crosslinking agent.

2. The underlying film composition for imprints of claim 1, wherein the urea-based crosslinking agent is a compound represented by the formula (I) below; 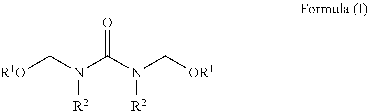
in the formula (I), each R¹ independently represents a hydrogen atom, or C₁₋₈ straight-chain or branched alkyl group, and each R² represents a hydrogen atom, or a C₁₋₁₁ substituent which may combine to each other to form a ring.

3. The underlying film composition for imprints of claim 1, wherein the urea-based crosslinking agent is represented by any one of the formulae (II) to (V) below; 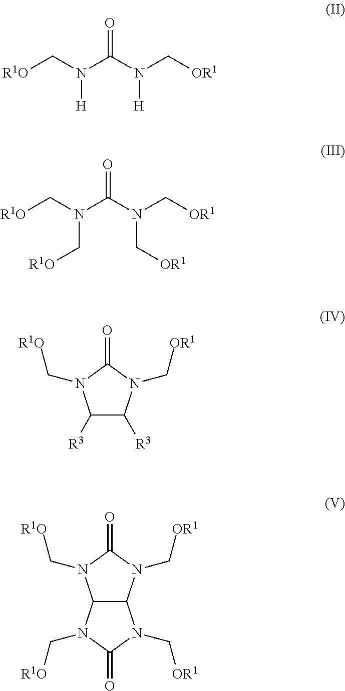
in the formulae (II) to (V), each R¹ independently represents a hydrogen atom, or C₁₋₈ straight-chain or branched alkyl group; each R³ independently represents a hydrogen atom, hydroxy group, or C₁₋₈ straight-chain or branched alkoxy group.

4. The underlying film composition for imprints of claim 3, wherein, in the formulae (II) to (V), each R¹ independently represents a hydrogen atom or methyl group, and each R³ independently represents a hydrogen atom, hydroxy group or methoxy group.

5. The underlying film composition for imprints of claim 1, which comprises 30% by mass or more of the curable main component to total components excluding a solvent.

6. The underlying film composition for imprints of claim 1, which comprises 1 to 50% by mass of the urea-based crosslinking agent to total components excluding a solvent.

7. The underlying film composition for imprints of claim 1, which further comprises 70% by mass or more of a solvent to total components.

8. The underlying film composition for imprints of claim 1, which comprises 30% by mass or more of the curable main component and 1 to 50% by mass of the urea-based crosslinking agent to total components; and further comprises 70% by mass or more of a solvent to total components excluding a solvent.

9. A cured product obtained by curing the underlying film composition for imprints described in claim 1.

10. A laminate comprising a base, an underlying film obtained by curing the underlying film composition for imprints described in claim 1, and a cured product of a curable composition for imprints.

11. The laminate described in claim 1, wherein the curable composition for imprints contains a polymerizable compound (C) and a polymerization initiator (D).

12. A pattern forming method comprising:
applying the underlying film composition for imprints described in claim 1 on a base, to form an underlying film;
applying a curable composition for imprints onto the underlying film;
curing the curable composition for imprints by photo-irradiation while keeping the curable composition for imprints and the underlying film held between the base and a mold with a fine pattern; and
releasing the mold.

13. The pattern forming method of claim 12, comprising:
applying the curable composition for imprints, after applying the underlying film composition for imprints onto the base, and after curing a part of the underlying film composition for imprints by heating or photo-irradiation.

14. A method of manufacturing a semiconductor device, the method comprising the pattern forming method described in claim 12.

15. An adhesion improving agent for improving adhesion between a curable composition for imprints and a base, the agent comprising a urea-based crosslinking agent.

16. The adhesion improving agent of claim 15, wherein the urea-based crosslinking agent is a compound represented by the formula (I) below; 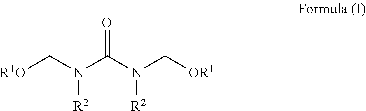
in the formula (I), each R¹ independently represents a hydrogen atom, or C₁₋₈ straight-chain or branched alkyl group, and each R² represents a hydrogen atom, or a C₁₋₁₁ substituent which may combine to each other to form a ring.

17. A semiconductor device manufactured by the method of manufacturing a semiconductor device of claim 14.

18. A kit comprising an underlying film composition for imprints and a curable composition for imprints;
wherein the underlying film composition for imprints comprises a curable main component and a urea-based crosslinking agent.

19. The kit described in claim 18, wherein the curable composition for imprints contains a polymerizable compound (C) and a polymerization initiator (D).

20. The kit described in claim 19, wherein the underlying film composition for imprints comprises 30% by mass or more of the curable main component and 1 to 50% by mass of the urea-based crosslinking agent to total components excluding a solvent; and further comprises 70% by mass or more of a solvent to total components excluding a solvent.
